(19) United States
(12) Patent Application Publication
(10) Pub. No.: US 2013/0015908 A1
(43) Pub. Date: Jan. 17, 2013

(54) TOUCH PANEL

(71) Applicants: PO-SHENG SHIH, Zhubei (TW); CHIEN-YUNG CHENG, Zhubei (TW); PO-YANG CHEN, Zhubei (TW); JIA-SHYONG CHENG, Zhubei (TW)

(72) Inventors: PO-SHENG SHIH, Zhubei (TW); CHIEN-YUNG CHENG, Zhubei (TW); PO-YANG CHEN, Zhubei (TW); JIA-SHYONG CHENG, Zhubei (TW)

(73) Assignee: SHIH HUA TECHNOLOGY LTD., Zhubei City (TW)

(21) Appl. No.: 13/542,926

(22) Filed: Jul. 6, 2012

(30) Foreign Application Priority Data
Jul. 12, 2011 (TW) 100124596

(51) Int. Cl. H03K 17/96; H05K 1/02

(52) U.S. Cl. 327/517; 174/268; 977/788

(57) ABSTRACT

A touch panel includes an insulating substrate, a rectangular transparent conductive layer and a number of electrodes. The insulating substrate has two opposite surfaces. The rectangular transparent conductive layer, fixed on one of the surfaces of the insulating substrate, has two opposite long sides and two opposite short sides. The electrodes are disposed at the short sides of the rectangular transparent conductive layer with a regular interval and electrically connected to the rectangular transparent conductive layer. The rectangular transparent conductive layer further has anisotropic impedance and defines an impedance direction substantially perpendicular to the short sides of the rectangular transparent conductive layer.

### CROSS-REFERENCE TO RELATED APPLICATIONS

This application claims all benefits accruing under 35 U.S.C. §119 from Taiwan Patent Application No. 100124596, filed on Jul. 12, 2011 in the Taiwan Intellectual Property Office, the disclosure of which is incorporated herein by reference.

### BACKGROUND

1. Technical Field

The present disclosure relates to a touch panel having a rectangular transparent conductive layer and a number of electrodes disposed at two opposite sides of the rectangular transparent conductive layer.

2. Description of Related Art

In recent years, various electronic apparatuses such as mobile phones, car navigation systems have advanced toward high performance and diversification. There is continuous growth in the number of electronic apparatuses equipped with optically transparent touch panels in front of their display devices such as liquid crystal panels. A user of such electronic apparatus operates it by pressing a touch panel with a finger or a stylus while visually observing the display device through the touch panel. Thus a demand exists for such touch panels with superior in visibility and reliability in operation. Due to a higher accuracy and a low-cost of the production, the resistance-type touch panels have been widely used.

A conventional resistance-type or capacitance-type touch panel includes a conductive indium tin oxide (ITO) layer as an optically transparent conductive layer. However, the ITO layer is generally formed by means of ion-beam sputtering and etched by laser beam, and the method is relatively complicated. Furthermore, the ITO layer has poor wear ability, low chemical endurance and uneven resistance in an entire area of the panel. Additionally, the ITO layer has a relatively low transparency. All the above-mentioned problems of the ITO layer produce a touch panel with low sensitivity, accuracy, and brightness.

What is needed, therefore, is to provide a touch panel which can overcome the shortcoming described above.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic view of one embodiment of a touch panel of the present disclosure.

FIG. 2 is a schematic view of one embodiment of an arrangement of a number of first conductive wires and a first rectangular transparent conductive layer of the touch panel shown in FIG. 1.

FIG. 3 is a schematic view of one embodiment of an arrangement of a number of second conductive wires and a second rectangular transparent conductive layer of the touch panel shown in FIG. 1.

FIG. 4 shows a Scanning Electron Microscope (SEM) image of one embodiment of a carbon nanotube film.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

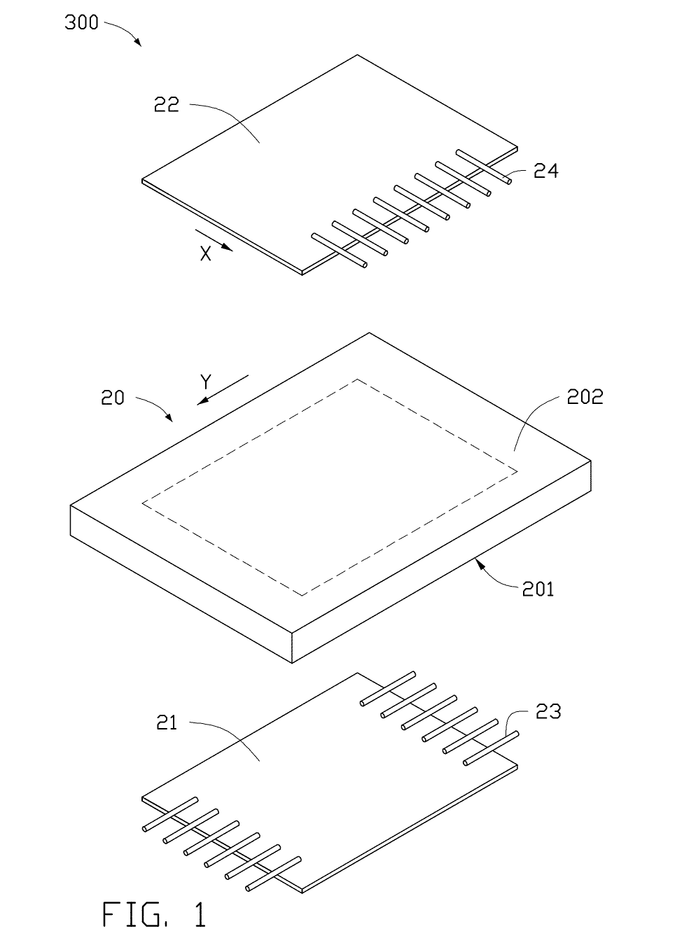

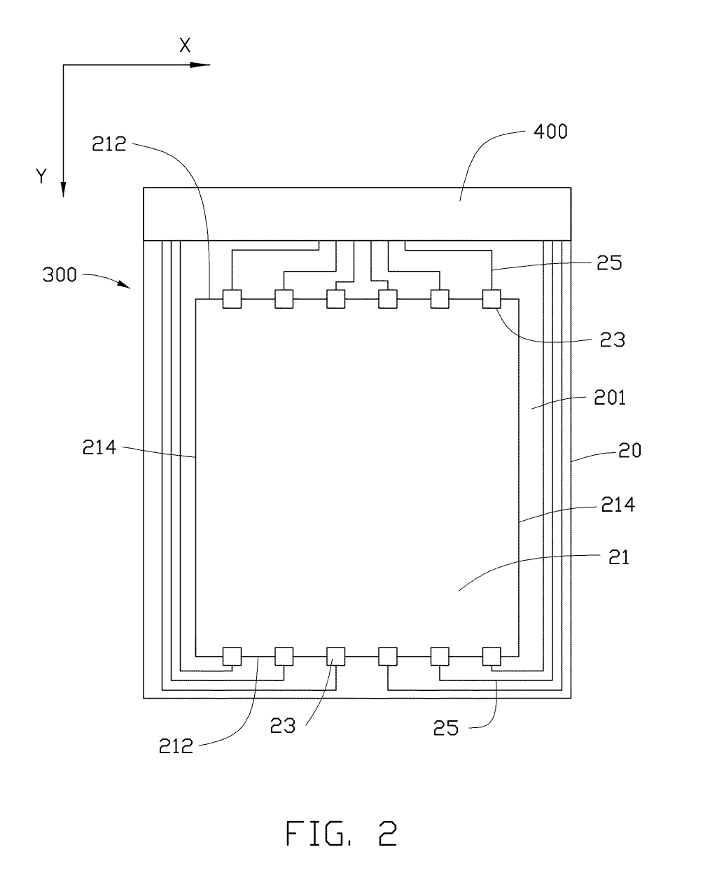

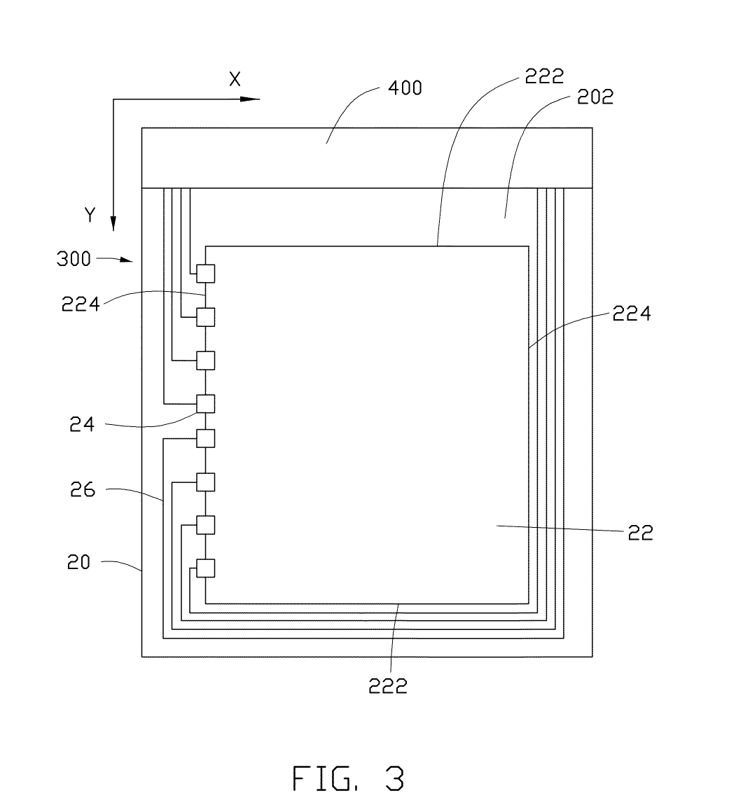

According to one embodiment, a touch panel 300 as illustrated in FIG. 1, FIG. 2 and FIG. 3 includes an insulating substrate 20, a first rectangular transparent conductive layer 21, a second rectangular transparent conductive layer 22, a number of first electrodes 23, a number of second electrodes 24, a number of first conductive wires 25, a number of second conductive wires 26, and a driving circuit 400.

The insulating substrate 20 has a first surface 201 and a second surface 202 opposite to the first surface 201. The first rectangular transparent conductive layer 21 is fixed on the first surface 201 of the insulating substrate 20, and has two opposite short sides 212 and two opposite long sides 214. The second rectangular transparent conductive layer 22 is fixed on the second surface 202 of the insulating substrate 20, and has two opposite short sides 222 and two opposite long sides 224. A first impedance is substantially parallel to an X axis shown in FIG. 1. The short sides 212 of the first rectangular transparent conductive layer 21 and the short sides 222 of the second rectangular transparent conductive layer 22 are substantially parallel to the X axis shown in FIG. 1, FIG. 2, and FIG. 3. The long sides 214 of the first rectangular transparent conductive layer 21 and the long sides 224 of the second rectangular transparent conductive layer 22 are substantially parallel to a Y axis shown in FIG. 1, FIG. 2, and FIG. 3.

The first electrodes 23 are symmetrically disposed at the short sides 212 of the first rectangular transparent conductive layer 21 with a first regular interval and electrically connected to the first rectangular transparent conductive layer 21. The first conductive wires 25 are fixed on the first surface 201 of the insulating substrate 20. The number of the first electrodes 23 is the same as the number of the first conductive wires 25. Each of the first conductive wires 25 has two ends. One end of each of the first conductive wires 25 is electrically connected to the driving circuit 400, and the other end of each of the first conductive wires 25 is electrically connected to a corresponding first electrode 23. Thus, the driving circuit 400 is electrically connected to the first rectangular transparent conductive layer 21 via the first conductive wires 25 and the first electrodes 23.

The second electrodes 24 are disposed at one of the long sides 224 of the second rectangular transparent conductive layer 22 with a second regular interval and electrically connected to the second rectangular transparent conductive layer 22. The second conductive wires 26 are fixed on the second surface 202 of the insulating substrate 20. The number of the second electrodes 24 is the same as the number of the second conductive wires 26. Each of the second conductive wires 26 has two ends. One end of each of the second conductive wires 26 is electrically connected to the driving circuit 400, and the other end of each of the second conductive wires 26 is electrically connected to a corresponding second electrode 24. Thus, the driving circuit 400 is electrically connected to the second rectangular transparent conductive layer 22 via the second conductive wires 26 and the second electrodes 24.

Accordingly, the driving circuit 400 detects a touch spot of the touch panel 300 because the driving circuit 400 is electrically connected to the first rectangular transparent conductive layer 21 and the second rectangular transparent conductive layer 22.

The insulating substrate 20 which supports the first rectangular transparent conductive layer 21 and the second rectangular transparent conductive layer 22 can be formed from transparent material, such as polyethylene (PE), polycarbonate (PC), polyethylene terephthalate (PET), polymethyl methacrylate (PMMA), glass, or quartz. In one embodiment, the insulating substrate 20 is glass.

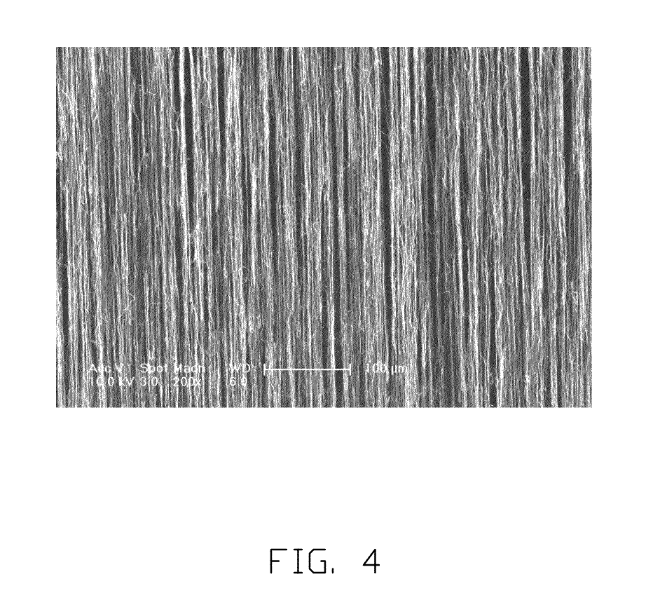

Referring to FIG. 4, the first rectangular transparent conductive layer 21 is a carbon nanotube layer formed by a drawn carbon nanotube film. The drawn carbon nanotube film can be pulled/drawn from a carbon nanotube array, and includes a number of successive and oriented carbon nanotubes joined end-to-end by van der Waals force therebetween.

The carbon nanotubes can be single-walled carbon nanotubes, double-walled carbon nanotubes, multi-walled carbon nanotubes, or any combination thereof. The diameter of the single-walled carbon nanotubes can be in the range from about 0.5 nm to about 50 nm. The diameter of the double -walled carbon nanotubes can be in the range from about 1 nm to about 50 nm. The diameter of the multi-walled carbon nanotubes can be in the range from about 1.5 nm to about 50 nm. The length of the carbon nanotubes can be greater than 50 um.

The drawn carbon nanotube film is a freestanding film, meaning that the drawn carbon nanotube film does not need to be supported by a substrate and can sustain the weight of itself when it is hoisted by a portion thereof without tearing. The drawn carbon nanotube film has minimum impedance along the stretching direction of the successive and oriented carbon nanotubes and maximum impedance along the direction perpendicular to the stretching direction of the successive and oriented carbon nanotubes so as to have anisotropic impedance. In one embodiment, the successive and oriented carbon nanotubes substantially extend perpendicular to the short sides 212 of the first rectangular transparent conductive layer 21. A first impedance direction of the first rectangular transparent conductive layer 21 is substantially defined as the stretching direction of the successive and oriented carbon nanotubes. The first impedance direction is substantially perpendicular to the short sides 212 of the first rectangular transparent conductive layer 21. A second impedance direction of the first rectangular transparent conductive layer 21 is defined as the direction substantially perpendicular to the stretching direction of the successive and oriented carbon nanotubes. The second impedance direction is substantially perpendicular to the long sides 214 of the first rectangular transparent conductive layer 21.

The second rectangular transparent conductive layer 22 can be an indium tin oxide (ITO) layer or an antimony tin oxide (ATO) layer. In addition, the second rectangular transparent conductive layer 22 includes a number of conductive traces extending substantially perpendicular to the long sides 224 of the second rectangular transparent conductive layer 22. The conductive traces can be formed from conductive material, such as metal, conductive polymer, conductive sizing, conductive glue, indium tin oxide, or antimony tin oxide.

A number of the second electrodes 24 disposed at one of the long sides 224 of the second rectangular transparent conductive layer 22 is greater than a number of the first electrodes 23 disposed at one of the short sides 212 of the first rectangular transparent conductive layer 21 for precision of the touch panel 300. In one embodiment, the touch panel 300 includes twelve first electrodes 23 and eight second electrodes 24. Thus, there are six first electrodes 23 disposed at one of the short sides 212 of the first rectangular transparent conductive layer 21 with the first regular interval. There are eight second electrodes 24 disposed at one of the long sides 224 of the second rectangular transparent conductive layer 22 with the second regular interval.

The first conductive wires 25 fixed on the first surface 201 of the insulating substrate 20 are disposed around the first rectangular transparent conductive layer 21 to form a first trace area. The second conductive wires 26 fixed on the second surface 202 of the insulating substrate 20 are disposed around the second rectangular transparent conductive layer 22 to form a second trace area. In one embodiment, there are twelve first conductive wires 25 fixed on the first surface 201 of the insulating substrate 20 because the number of the first electrodes 23 is the same as the number of the first conductive wires 25. An interval between the first conductive wires 25 is in a range from about 30 micrometers (μm) to about 80 μm. There are eight second conductive wires 26 fixed on the second surface 202 of the insulating substrate 20 because the number of the second electrodes 24 is the same as the number of the second conductive wires 26. An interval between the second conductive wires 26 is in a range from about 160 μm to about 200 μm.

The first trace area overlaps the second trace area to form a trace area of the touch panel 300. The trace area of the touch panel 300 is the first trace area when the first trace area is greater than the second trace area. On the contrary, the trace area of the touch panel 300 is the second trace area when the second trace area is greater than the first trace area.

Accordingly, the present disclosure is capable of providing a touch panel, detect a touch spot by a number electrodes disposed at two opposite sides of a rectangular transparent conductive layer and improve the precision of detecting the touch spot.

Finally, it is to be understood that the above-described embodiments are intended to illustrate rather than limit the present disclosure. Variations may be made to the embodiments without departing from the spirit of the disclosure as claimed. Elements associated with any of the above embodiments are envisioned to be associated with any other embodiments. The above-described embodiments illustrate the scope of the disclosure but do not restrict the scope of the disclosure.

What is claimed is:

1. A touch panel, comprising:
an insulating substrate having a first surface and a second surface opposite to the first surface;
a first rectangular transparent conductive layer with two opposite long sides and two opposite short sides fixed on the first surface of the insulating substrate; and
a plurality of first electrodes disposed at the short sides of the first rectangular transparent conductive layer with a first regular interval and electrically connected to the first rectangular transparent conductive layer,
wherein the first rectangular transparent conductive layer has anisotropic impedance and defines an impedance direction substantially perpendicular to the short sides of the first rectangular transparent conductive layer.

2. The touch panel as claimed in claim 1, further comprising a plurality of first conductive wires fixed on the insulating substrate, wherein each of the plurality of first conductive wires is electrically connected to a corresponding first electrode.

3. The touch panel as claimed in claim 1, wherein the first rectangular transparent conductive layer is a carbon nanotube layer.

4. The touch panel as claimed in claim 3, wherein the impedance direction substantially perpendicular to the short sides of the first rectangular transparent conductive layer is a minimal impedance direction.

5. The touch panel as claimed in claim 3, wherein the carbon nanotube layer is a carbon nanotube film comprising a plurality of successive and oriented carbon nanotubes joined end-to-end by van der Waals force therebetween.

6. The touch panel as claimed in claim 5, wherein the plurality of successive and oriented carbon nanotubes substantially extend perpendicular to the short sides of the first rectangular transparent conductive layer.

7. The touch panel as claimed in claim 1, further comprising:
a second rectangular transparent conductive layer with two opposite long sides and two opposite short sides fixed on the second surface of the insulating substrate; and
a plurality of second electrodes disposed at one of the long sides of the second rectangular transparent conductive layer with a second regular interval and electrically connected to the second rectangular transparent conductive layer.

8. The touch panel as claimed in claim 7, further comprising a plurality of second conductive wires fixed on the insulating substrate, wherein each of the plurality of second conductive wires is electrically connected to a corresponding second electrode.

9. The touch panel as claimed in claim 7, wherein the second rectangular transparent conductive layer comprises a plurality of conductive traces substantially extending perpendicular to the long sides of the second rectangular transparent conductive layer.

10. The touch panel as claimed in claim 7, wherein a number of the plurality of second electrodes disposed at one of the long sides of the second rectangular transparent conductive layer is greater than a number of the plurality of first electrodes disposed at one of the short sides of the first rectangular transparent conductive layer.

11. The touch panel as claimed in claim 7, wherein the second rectangular transparent conductive layer is selected from the group consisting of an indium tin oxide (ITO) layer and an antimony tin oxide (ATO) layer.

12. The touch panel as claimed in claim 1, further comprising a driving circuit disposed by one of the short sides of the first rectangular transparent conductive layer.

13. A touch panel, comprising:
an insulating substrate having a first surface and a second surface opposite to the first surface;
a first rectangular transparent conductive layer with two opposite long sides and two opposite short sides fixed on the first surface of the insulating substrate;
a plurality of first electrodes disposed at the short sides of the first rectangular transparent conductive layer with a first regular interval and electrically connected to the first rectangular transparent conductive layer;
a plurality of first conductive wires fixed on the insulating substrate, each of the plurality of first conductive wires being electrically connected to a corresponding first electrode;
a second rectangular transparent conductive layer with two opposite long sides and two opposite short sides fixed on the second surface of the insulating substrate;
a plurality of second electrodes disposed at one of the long sides of the second rectangular transparent conductive layer with a second regular interval and electrically connected to the second rectangular transparent conductive layer; and
a plurality of second conductive wires fixed on the insulating substrate, each of the plurality of second conductive wires being electrically connected to a corresponding second electrode,
wherein the first rectangular transparent conductive layer has anisotropic impedance and defines an impedance direction substantially perpendicular to the short sides of the first rectangular transparent conductive layer.

14. The touch panel as claimed in claim 13, wherein the first rectangular transparent conductive layer is a carbon nanotube layer.

15. The touch panel as claimed in claim 14, wherein the impedance direction substantially perpendicular to the short sides of the first rectangular transparent conductive layer is a minimal impedance direction.

16. The touch panel as claimed in claim 14, wherein the carbon nanotube layer is a carbon nanotube film comprising a plurality of successive and oriented carbon nanotubes joined end-to-end by van der Waals force therebetween.

17. The touch panel as claimed in claim 16, wherein the plurality of successive and oriented carbon nanotubes substantially extend perpendicular to the short sides of the first rectangular transparent conductive layer.

18. The touch panel as claimed in claim 13, wherein the second rectangular transparent conductive layer comprises a plurality of conductive traces substantially extending perpendicular to the long sides of the second rectangular transparent conductive layer.

19. The touch panel as claimed in claim 13, wherein a number of the plurality of second electrodes disposed at one of the long sides of the second rectangular transparent conductive layer is greater than a number of the plurality of first electrodes disposed at one of the short sides of the first rectangular transparent conductive layer.

20. The touch panel as claimed in claim 13, wherein the second rectangular transparent conductive layer is selected from the group consisting of an indium tin oxide layer and an antimony tin oxide layer.
